(19) United States
(12) Patent Application Publication
(10) Pub. No.: US 2025/0202201 A1
(43) Pub. Date: Jun. 19, 2025

(54) RECESS-ETCHED REGROWN VCSEL

(71) Applicant: AMS SENSORS ASIA PTE. LTD., Singapore (SG)

(72) Inventors: Jean-Francois SEURIN, Princeton Junction, NJ (US); Yu ZHANG, Princeton, NJ (US); Su San Win KHIN, Singapore (SG)

(21) Appl. No.: 18/867,018

(22) PCT Filed: Jun. 21, 2023
(86) PCT No.: PCT/SG2023/050438

§ 371 Date: Nov. 19, 2024

(30) Foreign Application Priority Data
Jun. 22, 2022 (GB) 2209141.7

(51) Int. Cl. H01S 5/183; H01S 5/42

(52) U.S. Cl. CPC H01S 5/18308; H01S 5/18358; H01S 5/18377; H01S 5/18394; H01S 5/423

(57) ABSTRACT

A semiconductor vertical cavity surface emitting laser (VCSEL), the VCSEL comprising a first mirror region forming a lower distributed Bragg reflector and a second mirror region forming an upper distributed Bragg reflector, the upper distributed Bragg reflector and the lower distributed Bragg reflector defining a vertical resonant cavity comprising an inner region and an outer region. The VCSEL further comprises a resistive structure comprising a resistive portion in the outer region and an etched portion located in the inner region of the vertical resonant cavity, such that a conducting channel is formed in the inner region.

### CROSS-REFERENCE TO RELATED APPLICATIONS

This application is a US National Stage application, filed under 35 U.S.C. § 371, of International Application PCT/SG2023/050438, filed on Jun. 21, 2023, and claims priority to British application 2209141.7, filed on Jun. 22, 2022, the entirety of the above listed applications is incorporated herein by reference.

### FIELD

Various embodiments of the present application relate to a semiconductor light source, in particular the disclosure relates to a vertical cavity surface emitting laser (VCSEL) having a resistive structure with an etched, recess portion.

### BACKGROUND

Proton implanted VCSELs make use of implantation to create a high resistance region in order to guide the current flow to a small region of the laser's active layers. However, the implantation cannot create strong index change so that the lasing mode lacks index guiding. Therefore, optical confinement in proton implanted VCSELs is poor or not stable due to thermal lensing effects. Furthermore, the implantation can cause damage to the crystal, which can cause optical loss for the lasing mode. To avoid damage in the active region, in some devices the implanted region is located away from the active region, but this introduces undesirable current spreading, i.e. reduced transverse current confinement. It is also difficult to control the implant depth, position and size, which can cause problems in mass production.

Oxide confinement VCSELs include a high-Aluminum-content AIGaAs layer that is converted into a transparent native oxide by reaction with water vapor at an elevated temperature. The subsequently formed oxide layer is an insulator and can be used for current confinement. The oxide layer also causes blue shift of the optical cavity resonant wavelength in the current blocking region relative to the laser cavity resonator wavelength, thereby providing optical confinement by index guiding.

This wet oxidation process results in poor size control and non-uniformity, limiting the reproducibility and yield for manufacturing, especially for small devices. The oxidation process also introduces dislocations and other defects at the oxide and semiconductor interface. The volume change occurring during oxidation creates a mechanical strain field. The difference of thermal expansion coefficients of the oxide and the adjacent semiconductor layers adds up to the strain field and degrades the device reliability. The defects can be furthermore driven by the strain field to migrate towards the active region where the defects then act as non-radiative recombination centers, thus rendering the device non-functional. This leads to reliability problems for oxide VCSELs. In addition, the oxide blocks heat and therefore stops heat spreading from the upper semiconductor DBRs (distributed Bragg reflectors); this causes device selfheating which limits the maximum output power and saturates modulation speed.

Due to the lateral space needed for the etching and oxidation process on either side of each oxide confinement VCSEL, the device density of oxide VCSEL arrays is strongly limited. Typically the lateral dimension of each oxide region is greater than or equal to 7 pm and the lateral distance between adjacent VCSELs is greater than or equal to 4 pm. This means that for oxide confinement VCSELs, the minimum device center to center distance is approximately 18 pm.

In mesa-type diffused VCSELs, a phase shift mesa region is defined in the center of the device by lithography and wet etching (protecting the center portion of the device and etching the surroundings). The phase shift mesa region will have a cavity resonator wavelength in the center portion of the device that is longer than the resonant wavelength of the surrounding blocking region, thereby providing optical mode index guiding. A high conductivity channel is formed underneath the phase shift mesa region by dopant diffusion of the center region underneath the phase shift mesa region. The surrounding blocking region will be highly depleted without dopant diffusion. Alternatively, the surrounding blocking region can be diffused or implanted to form a high resistance region while the center part is not diffused. The dopant diffusion process can be very challenging, and it is very difficult to obtain a well-defined diffused dopant profile during regrowth.

VCSELs are described in U.S. Pat. No. 9,705,283 B1, US2018/0019572 A1, US2019/0020177 A1, U.S. Pat. No. 10,483,719 B2, U.S. Pat. No. 20,050,063440A, U.S. Pat. No. 20,050,249254, U.S. Pat. No. 8,774,246 B1, U.S. Pat. No. 9,705,283, U.S. Pat. No. 6,396,865, and U.S. Pat. No. 6,551,936 B2.

Further VCSELs are described in: K. Tai, R. J. Fischer, K. W. Wang, S. N. G. Chu, and A. Y. Cho, “Use of implant isolation for fabrication of vertical cavity surface-emitting laser diodes,” Electron. Lett. 25, 1644-1645 (1989); R. A. Morgan, M. K. Hibbs-Brenner, R. A. Walterson, J. A. Lehman, et al, “Producible GaAs-based MOVPE-grown verticalcavity top-surface emitting lasers with record performance,” Electron. Lett. 31, 462-464 (1995); D. L. Huffaker, D. G. Deppe, K. Kumar, and T. J. Rogers, “Native-oxide defined ring contact for low threshold vertical-cavity lasers,” Appl. Phys. Lett. 65, 97 (1994); K. D. Choquette, R. P. Schneider, Jr., K. L. Lear and K. M. Geib, “Low threshold voltage vertical-cavity lasers fabricated by selective oxidation,” Electron. Lett. 30, 2043-2044 (1994); G. Ronald Hadley, “Effective index model for vertical-cavity surface-emitting lasers,” Opt. Lett. 20, 1483-1485 (1995); “A GaAs-based self-aligned stripe distributed feedback laser”, H Lei et al, Semicond. Sci. Technol. 31 (2016) 085001; Mawst, Luke J. ““Anti” up the aperture” IEEE Circuits and Devices Magazine 19 (2003): 34-41; Z. Jin, R. S. Tummidi, Y. P. Gupta, D. M. Schindler, and N. Tansu, “Quasi-Guided-Optical-Waveguide VCSELs for Single-Mode High-Power Applications,” in Conference on Lasers and Electro-Optics/Quantum Electronics and Laser Science Conference and Photonic Applications Systems Technologies, Technical Digest (CD) (Optical Society of America, 2006), paper CWP7; and Lu, D. & an, Junwoo & Huang, H. & Deppe, D. (2004). All-epitaxial mode-confined vertical-cavity surface-emitting laser. Applied Physics Letters. 85. 2169-2171. 10.1063/1.1795982.

### SUMMARY

In general, this disclosure proposes to overcome at least some of the above problems by providing a VCSEL having a recess-etched resistive structure having a resistive portion including one or more layers of undoped or different type of semiconductor material surrounding an etched window region. The resistive portion provides current blocking, whilst the placement and thickness of the resistive structure is configured to provide optical index guiding or anti-guiding.

According to a first aspect of the disclosure, there is provided a semiconductor vertical cavity surface emitting laser (VCSEL), comprising:
a first mirror region forming a lower distributed Bragg reflector;
a lower cavity spacer layer located over the lower distributed Bragg reflector; an active region located over the lower cavity spacer layer;
an upper cavity spacer layer located over the active region;
a second mirror region located over the upper cavity spacer layer, wherein the second mirror region forms an upper distributed Bragg reflector, and
wherein the upper distributed Bragg reflector and the lower distributed Bragg reflector define a vertical resonant cavity, and wherein the vertical resonant cavity comprises an inner region and an outer region, and
a resistive structure located between the upper cavity spacer layer and the second mirror region, wherein the resistive structure comprises:
a resistive portion in the outer region and an etched portion located in the inner region of the vertical resonant cavity, such that a conducting channel is formed in the inner region.

The resistive structure provides current confinement for the VCSEL. The etched region and the resistive portion of the resistive structure can operate as a central phase shift window.

The VCSEL can be manufactured without an oxidation process, thereby improving reproducibility and yield and allowing manufacture of a dense VCSEL array. This is because oxidation relies on a timed process to form an aperture, whereas the regrowth process relies on a photolithographic step, which is much more precise, uniform, and reproducible. The VCSEL can also have lower thermal resistance and less internal strain, so that it is more reliable than state-of-the-art devices.

The VCSEL can be produced without a wet oxidation procedure, this improves device reproducibility and yield due to improved scaling and uniformity throughout the full wafer. Highly dense VCSEL arrays can be manufactured, as the distance between adjacent VCSELs in an array may only be limited by lithography of the resistive structure. Furthermore, there is no requirement for a dopant diffusion process during regrowth.

The resistive structure may be configured such that a first resonant wavelength of the inner region of the vertical resonant cavity is different to a second resonant wavelength of the outer region of the vertical resonant cavity. The resistive portion of the resistive structure can alter the effective cavity length in the outer region relative to the effective cavity length in the inner region of the VCSEL. This change in effective cavity length can cause either an increase or decrease of the cavity resonant wavelength in the outer region.

The semiconductor VCSEL may further comprise a third mirror region located between the upper cavity spacer layer and the resistive structure. The second mirror region and the third mirror region may form the upper distributed Bragg reflector.

The second mirror region may be in direct contact with the third mirror region in the inner region. In other words, there may be no resistive portion in the inner region.

The resistive structure may comprises a first resistive layer. The third mirror region and the first resistive layer may have a high etch selectivity. In other words, the materials used for the first resistive layer and the third mirror region etch at significantly different etch rates when exposed to a given etchant. This allows the first resistive layer to be etched, and the etch process stop on the surface of the third mirror region.

The resistive structure may further comprise a second resistive layer. The second resistive layer may be located over the first resistive layer. The first resistive layer and the second resistive layer may have a high etch selectivity. This allows the second resistive layer to be etched, and the etch process stop on the surface of the first resistive layer.

The resistive portion may be configured such that the outer region of the vertical resonant cavity has a lower effective refractive index than the effective refractive index of the inner region. This provides optical guiding.

The resistive portion may have an optical thickness which is greater than a quarter wavelength of the first resonant wavelength of the inner region and less than a half wavelength of the first resonant wavelength of the inner region.

The resistive portion may be configured such that the outer region of the vertical resonant cavity has a higher effective refractive index than the effective refractive index of the inner region of the vertical resonant cavity. This provides anti-guiding.

The resistive portion may have an optical thickness which is less than a quarter wavelength of the first resonant wavelength of the inner region or greater than a half wavelength of the first resonant wavelength of the inner region.

The resistive portion may comprise at least one epitaxially grown layer. By epitaxially growing the resistive portion, the thickness of the resistive portion can be controlled very precisely such that the strength of guiding or anti-guiding provided by the VCSEL can be controlled.

The second mirror region may be epitaxially grown over the resistive portion and the etched portion.

The resistive portion may comprise an undoped semiconductor.

The upper distributed Bragg reflector may comprise a semiconductor material of a first conductivity type and the resistive portion may comprise a semiconductor material of a second conductivity type. For example, the upper distributed Bragg reflector may comprise an n-type semiconductor material and the resistive portion may comprise a p-type semiconductor material, or the upper distributed Bragg reflector may comprise a p-type semiconductor material and the resistive portion may comprise an n-type semiconductor material.

According to a further aspect of the disclosure, there is provided a VCSEL array comprising a plurality of semiconductor VCSELs as described above. An outer region of a first VCSEL of the plurality of VCSELs may be in direct contact with an outer region of a second VCSEL of the at least two semiconductor VCSELs.

The plurality of VCSELs may be configured such that leaked radiation from the inner region of a first VCSEL of the plurality of VCSELs interferes with leaked radiation from the inner region of a second VCSEL of the plurality of VCSELs. The plurality of VCSELs in the array of VCSELs may be configured to each provide anti-guiding, this allows the light within each inner region to overlap with the light from an inner region of an adjacent VCSEL. This allows formation of a VCSEL array having greater coherence between the VCSELs in the array and results in a brighter beam from the VCSEL array.

According to a further aspect of the disclosure, there is provided a semiconductor VCSEL, wherein the VCSEL is made using a method comprising:
forming a first mirror region forming a lower distributed Bragg reflector; forming a lower cavity spacer layer located over the lower distributed Bragg reflector;
forming an active region located over the lower cavity spacer layer;
forming an upper cavity spacer layer located over the active region; forming a second mirror region located over the upper cavity spacer layer, wherein the second mirror region forms an upper distributed Bragg reflector, and wherein the upper distributed Bragg reflector (114) and the lower distributed Bragg reflector define a vertical resonant cavity, and wherein the vertical resonant cavity comprises an inner region and an outer region, and
forming a resistive structure located between the upper cavity spacer layer and the second mirror region, wherein the resistive structure comprises:
a resistive portion in the outer region and an etched portion located in the inner region of the vertical resonant cavity, such that a conducting channel is formed in the inner region, and wherein the resistive structure is made using the steps of:
forming a first resistive layer;
forming a second resistive layer over the first resistive layer, wherein the first resistive layer and the second resistive layer have a high etch selectivity;
forming a semiconductor layer over the second resistive layer, wherein the semiconductor layer and the second resistive layer have a high etch selectivity, and wherein the semiconductor layer and the first resistive layer have a low etch selectivity;
forming a mask over the semiconductor layer and patterning the mask to define the inner region;
selectively etching the semiconductor layer in the inner region; selectively etching the second resistive layer in the inner region; removing the mask; and
after removing the mask, etching the semiconductor layer in the outer region and the first resistive layer in the inner region (120).

The proposed device provides the following advantages:
the recess-etched resistive structure provides optical index guiding (optical confinement) or anti-guiding and current blocking (current confinement);
the manufacturing process of the VCSELs has no wet oxidation process, which limits reproducibility and yield in manufacturing;
as there is no oxidation process required, this enables the production of highly dense VCSEL arrays compared with state-of-the-art VCSELs;
the disclosed VCSELs have lower thermal resistance and less internal strain, so that the devices are more reliable due to low thermal resistance;
the device's maximum output power is increased; and
the manufacturing process of the VCSEL does not include a dopant diffusion process during regrowth, thereby simplifying the manufacturing process.

The herein disclosed VCSELs thus:
can be produced with greater reproducibility and with higher yield;
are more reliable;
can have a greater maximum output power;
can be positioned very closely to one another on a wafer, enabling very dense laser arrays.

The recess-etched resistive structure can be used, most importantly for VCSELs, and in particular in commercial VCSELs.

### BRIEF DESCRIPTION OF THE DRAWINGS

Some embodiments of the disclosure will now be described, by way of example only and with reference to the accompanying drawings, in which:

FIG. 1 illustrates schematically a vertical cavity surface emitting laser (VCSEL);

FIG. 2 shows the resonant wavelength of the periphery region against the thickness of the resistive portion of the resistive structure;

FIG. 3 illustrates schematically an array of VCSELs;

FIG. 4, FIGS. 4 (a)-4 (d) show a method for manufacturing a resistive structure in a VCSEL;

FIG. 5, FIGS. 5 (a)-5 (e) show an alternative method for manufacturing a resistive structure in a VCSEL; and

FIG. 6, FIGS. 6 (a)-6 (e) show a further, alternative method for manufacturing a resistive structure in a VCSEL.

### DETAILED DESCRIPTION

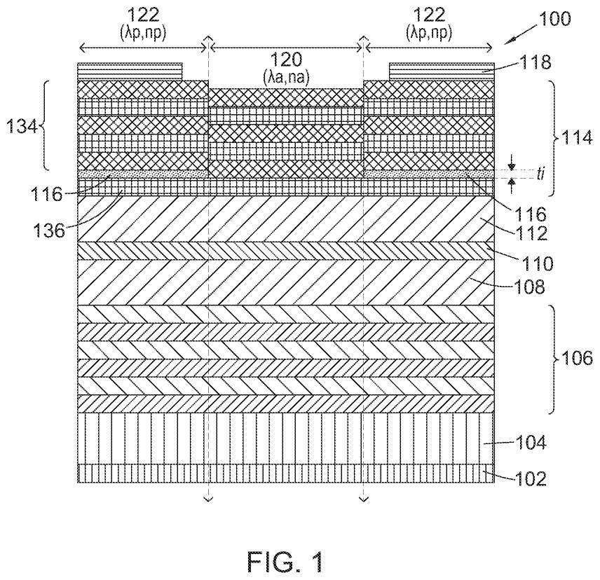

FIG. 1 illustrates a schematic cross-section of a vertical cavity surface emitting laser (VCSEL) 100. The VCSEL 100 includes a lower distributed Bragg reflector 106 operating as a first mirror region located over a substrate 104. A lower cavity spacer 108 is formed over the lower distributed Bragg reflector (DBR) 106, and an active region 110 is located between the lower cavity spacer 108 and an upper cavity spacer 112. An upper distributed Bragg reflector 114 is located over the upper cavity spacer 112. The lower and upper distributed Bragg reflectors 106, 114 define a vertical resonant cavity therein between.

The upper distributed Bragg reflector 114 includes a resistive structure located between the upper cavity spacer layer 112 and a second mirror region 134 of the upper distributed Bragg reflector 114. The layers of the upper DBR 114 and/or the lower DBR 106 can be formed of alternating layers of two materials, for example AIGaAs (e.g., with 88 to 92% Al) and GaAs (e.g., with 0 to 10% Al).

The upper distributed Bragg reflector (DBR) 114 may also include a further mirror region 136, where the resistive structure is formed between the two mirror regions 134, 136. The third mirror region 136 of the VCSEL is optional, and may include one layer or two or more sub-layers. In embodiments with a third mirror region 136, this forms a layer of the upper DBR 114, for example the third mirror region 136 can be made of GaAs (e.g., with 0 to 10% Al).

The resistive structure includes a resistive or current blocking portion 116 laterally surrounding an etched portion of the resistive structure. The etched portion may be referred to as a window or aperture through the resistive portion 116. The resistive portion 116 defines an outer or periphery region 122 and the etched portion defines an inner or aperture region 120 in which a conducting channel is formed. FIG. 1 shows a cross-section through the VCSEL 100; in a plan view the device may have a cylindrical shape such that the resistive portion 116 comprises a ring shaped portion surrounding the etched portion. Whilst FIG. 1 shows the resistive structure located towards a lower region of the upper DBR 114, the resistive portion 116 can be positioned further above in the upper DBR layer stack 114.

Metal contacts 102, 118 are located on a lower surface of the substrate 104 and an upper surface of the mirror region 134 of the upper distributed Bragg reflector 114 in the outer region 122.

The substrate 104 may be produced in an initial base epi growth. The semiconductor layers of the VCSEL 100 can all be epitaxially grown.

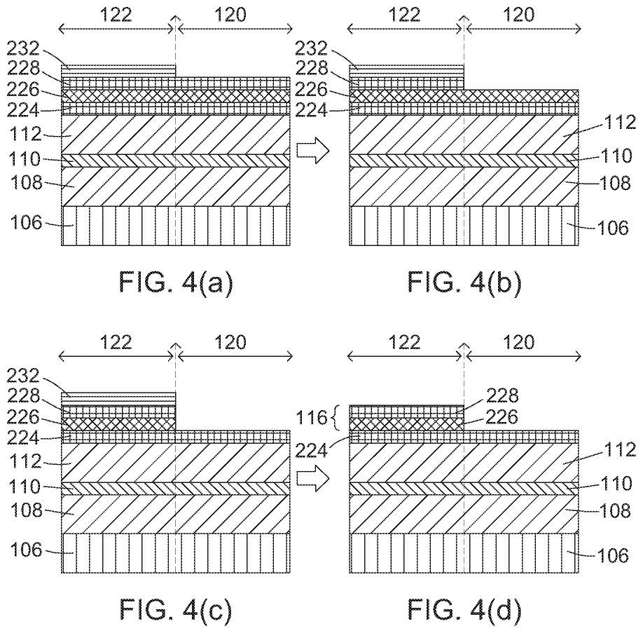

The current-blocking layer or resistive portion 116 can include one layer or may include two or more sub-layers, e.g., a GaAs layer on an InGaP layer. The resistive structure within the upper DBR 114 is a recess etched regrown structure, as shown in FIGS. 4 to 6. A first layer (or set of sub-layers) is epitaxially grown and stops within the upper DBR 114, with one or more current blocking layers at the surface. After this first growth step, a recess etch is performed to form an etched portion laterally surrounded by the current blocking layer 116, defining the inner region 120 surrounded by the outer region 122. The second mirror region 134 of the upper DBR 114 is then epitaxially grown over the entire surface of the resistive portion 116 and the etched portion of the resistive structure.

The current blocking layers 116 can be formed of an undoped semiconductor or a different type of semiconductor to the mirror regions 136, 134 of the upper DBR 114 to form a highly depleted resistant region. For example, the resistive portion can be an n-type semiconductor if the mirror regions 136, 134 of the upper DBR 114 are a p-type semiconductor, and vice versa. For example, if the mirror regions 134, 136 of the upper DBR 114 are made with AIGaAs material system (e.g. alternating layers of GaAs (e.g., with 0 to 10% Al) and AIGaAs (e.g., with 88 to 92% Al)), the current blocking region 116 could be a two-layer structure with a layer of GaAs on top of a layer of InGaP, or it can be just a single layer of InGaP.

The recess-etched window or resistive structure provides current confinement for the VCSEL 100. The resistive portion 116 is a peripheral undoped or different semiconductor region and provides current blocking in the outer region 122 to form a conducting channel in the inner region 120. By confining the current and forming a conducting channel through the inner region 120 of the device, the current only drives emission in the inner region 120 and doesn't drive emission underneath the top contacts 118; this improves the efficiency of the VCSEL 100.

The VCSEL 100 can be manufactured without an oxidation process, thereby improving reproducibility and yield and allowing manufacture of a dense VCSEL array. The VCSEL 100 will also have lower thermal resistance and less internal strain, so that it is more reliable than state-of-the-art devices. Furthermore, there is no requirement for a dopant diffusion process during regrowth.

The etched region and the current blocking region 116 of the resistive structure operate as a central phase shift window. The placement of the current blocking layers or resistive portion 116 within the upper DBR 114 causes the vertical cavity resonant wavelength Aₐ at the inner region 120 to be different to the vertical cavity resonant wavelength Aₚ of the outer region 122.

In the recess-etched, regrown VCSEL shown in FIG. 1, the physical thickness of the resistive portion 116 of the resistive structure in the periphery region 122 is thicker than the resistive structure in the aperture region 120. In the VCSEL 100, rather than introduce a relative phase shift of the resonant wavelength Aₐ within the inner region 120, the thicker region including the resistive portion 116 acts as a surrounding phase shift region, causing a relative phase shift of the cavity resonator wavelength Aₚ within the outer region 122. The resistive portion 116 of the resistive structure alters the effective cavity length in the outer region 122 relative to the effective cavity length in the inner region 120 of the VCSEL 100. This change in effective cavity length causes either an increase (red shift) or decrease (blue shift) of the cavity resonant wavelength Aₚ in the outer region 122. The longitudinal placement and thickness ti of the resistive portion 116 and etched portion of the resistive structure will determine the blue or red shift of the cavity resonant wavelength Aₚ at the peripheral or outer region 122 so that optical guiding or anti-guiding can be achieved.

A change of the cavity resonant wavelength Aₚ in the outer region 122 is equivalent to a change of effective index np in the outer region 122 according to the approximate equation An/n=AA/A, where An/n=(nₐ−nₚ)/nₐ and AA/A=(Aₐ−Aₚ)/Aₐ.

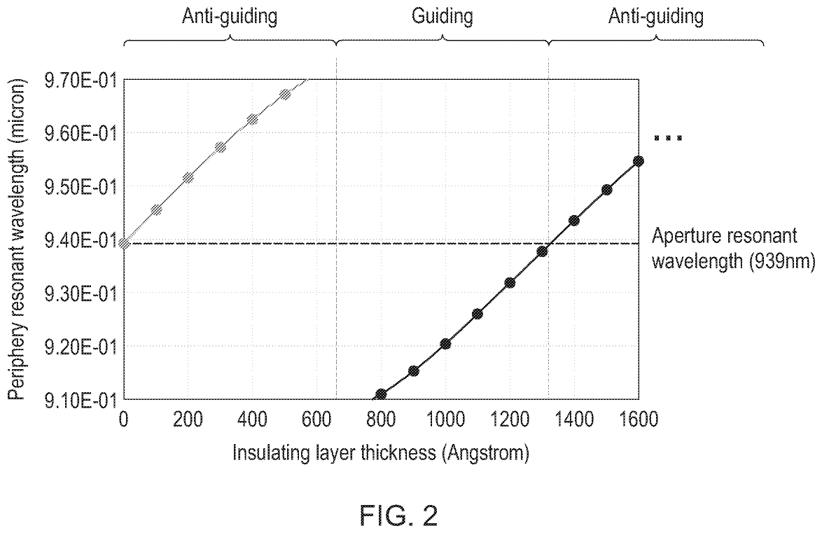

FIG. 2 shows the resonant wavelength Aₚ of the periphery region 122 of FIG. 1 as a function of the physical thickness ti of the resistive portion 116 of the resistive structure, whilst keeping the thickness of the aperture region constant (meaning the regrown portion of the structure doesn't change) so that the resonant wavelength Aₐ of the aperture region remains unchanged (Aₐ ˜939 nm in the example shown in FIG. 2).

In a VCSEL, a given resonant wavelength is periodic with respect to the cavity thickness between the two mirrors of the resonator. The period is a half-wavelength in optical thickness. Within this half-wavelength thickness variation, the resonant wavelength will vary, covering a range of values both greater and smaller than the original resonant wavelength.

As the thickness ti of the resistive portion 116 is increased, the structure goes from an anti-guiding regime (Aₚ>Aₐ), to a guiding regime (Aₚ<Aₐ), and as the thickness ti of the resistive portion 116 is further increased then the structure goes again to an antiguiding regime. The switch between anti-guiding and guiding occurs every quarterwavelength in optical thickness (approximately every 666A in physical thickness in this example), where optical thickness is defined as refractive index of the resistive material multiplied by the thickness of the material. If the thickness ti of the resistive portion 116 were to be further increased beyond that shown in FIG. 2, the structure would go

again from an anti-guiding regime to a guiding regime, and then again to an antiguiding regime—changing from guiding to anti-guiding or anti-guiding to guiding at every quarter-wavelength in optical thickness.

For etch recess regrown VCSELs with a thin resistive region having a thickness ti in the order of 10's of nm (20 nm for example), this corresponds to an anti-guiding structure.

As shown in FIG. 2, ti can be increased to the next quarter-wavelength in optical thickness so that the VCSEL becomes a guiding structure (this corresponds to ti ˜800A to 1300A in the example shown in FIG. 2).

Furthermore, the guiding strength can be precisely controlled by altering the thickness ti of the resistive region to be a value in the guiding range of ti values. In the example shown, t/=1000A will yield a stronger optical guiding than t/=1200A. This is because there is a greater difference between the resonant wavelength Aₚ in the periphery region 120 when t/=1000A and the aperture resonant wavelength Aₐ than the difference between the resonant wavelength Aₚ in the periphery region 120 when t/=1200A and the aperture resonant wavelength Aₐ.

Stronger optical guiding allows lasing in a larger number of transverse modes, and allows lasing with a higher divergence.

Anti-guiding

In a first embodiment, the thickness ti of the resistive portion may be less than 100 nm thin (it may typically be in the region of 10 to 30 nm). The optical thickness of the resistive region 116 within the periphery region 122 may be less than a quarterwavelength of the resonant wavelength Aₐ of the aperture region 120, this resulting in the resonant wavelength Aₚ of the periphery region 122 being longer than the resonant wavelength Aₐ of the aperture region 120. In other words, the thicker surrounding region (surrounding the recess-etched window) including the resistive portion 116 causes a red shift of the VCSEL cavity resonator wavelength Aₚ within the outer region 122, such that Aₚ>Aₐ.

This in turn, results in an effective negative index contrast between the aperture and the periphery regions (nₚ>nₐ), such that An/n<0 which results in anti-guiding. Antiguiding does not confine the optical mode to the inner region 120.

Individual anti-guided VCSEL cavities have lower optical performance (e.g. higher threshold current, lower power-conversion-efficiency) because of poor modal overlap with the gain region. As there is no intrinsic cavity guiding mechanism, the mode diameter will be large compared to the diameter of the pumped gain region such that a large portion of the mode will experience losses in the un-pumped periphery region.

However, when an array of VCSELs each having anti-guiding are provided adjacent to each other, the light within each inner region 120 overlaps with the light from an inner region 120 of an adjacent VCSEL. This ensures greater coherence between the VCSELs in the array and results in a brighter beam from the VCSEL array.

Guiding

In a further embodiment, the optical thickness of the resistive region ti may be greater than a quarter wavelength of the resonant wavelength Aₐ of the aperture region. When ti is increased from zero and reaches an optical thickness of an odd number of quarter wavelengths of the resonant wavelength Aₐ of the aperture region, there will be a transition leading to a sudden decrease in the resonant wavelength Aₚ of the periphery region 122. If the thickness ti increases from a value of a quarter wavelength of the resonant wavelength Aₐ but remains less than two quarter wavelengths of the resonant wavelength Aₐ, then Aₚ will then continue to increase with increasing ti, but from values now lower than Aₐ.

The thickness ti of the resistive region 116 is set in the second (or any even numbered) quarter-wavelength of the resonant wavelength Aₐ of the aperture region such that Aₚ<Aₐ. This in turn, results in an effective positive index contrast between the aperture and the periphery regions (nₚ<nₐ), such that An/n>0 which results in guiding.

In this example, the thicker surrounding region (surrounding the recess-etched window) including the resistive portion 116 causes a blue shift (decrease) of the VCSEL cavity resonator wavelength Aₚ within the outer region 122. In other words, the device may be configured such that Aₐ>Aₚ in order to achieve optical confinement, however this is done by purposefully decreasing Aₚ using the resistive portion 116. This provides guiding, which confines the optical mode to the inner region 120 and results in a less lossy VCSEL device.

As the layers of the resistive structure and the distributed Bragg reflector 114 are epitaxially grown, this growth process can be controlled very precisely such that the strength of guiding or anti-guiding provided by the VCSEL 100 can be controlled.

The guiding strength can be precisely controlled by altering the thickness ti whilst remaining within the range of thickness ti values that introduce optical guiding. In the example shown in FIG. 2, a thickness t/=1000A will yield stronger optical guiding than a thickness t/=1200A. Increased guiding will allow lasing in a larger amount of transverse modes, and also with a higher divergence.

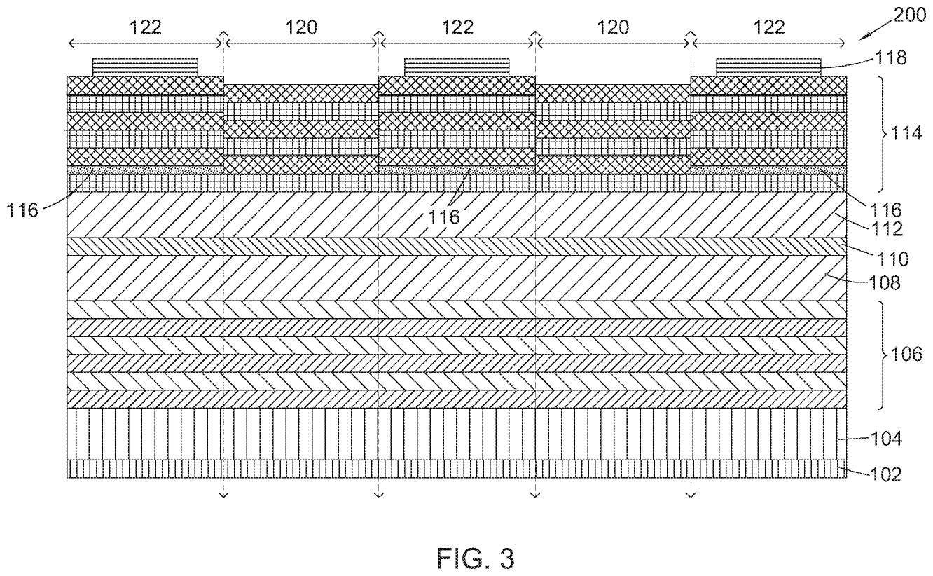

FIG. 3 illustrates a schematic cross-section of an array of VCSELs 200 as shown in FIG. 1. As discussed in relation to FIG. 1, the VCSELs can be produced without a wet oxidation procedure, this improves device reproducibility and yield due to improved scaling and uniformity throughout the full wafer. Highly dense VCSEL arrays can be manufactured, as the distance between adjacent VCSELs in the array 200 is only limited by lithography of the resistive structure.

The VCSELs in the array 200 may be anti-guided, this allows leaked radiation from the inner region 120 of a first VCSEL of the plurality of VCSELs to interfere with leaked radiation from the inner region 120 of a second VCSEL of the plurality of VCSELs in the VCSEL array. This allows a VCSEL array having greater coherence between the VCSELs in the array and results in a brighter beam from the VCSEL array to be provided.

FIG. 4 (referring collectively to FIGS. 4(a) to 4(d)) shows a method for manufacturing a resistive structure in a VCSEL 100, such as that shown in FIGS. 1 and 3. The method includes forming a third mirror region 224 over a lower DBR 106 and a laser cavity 108, 112 including an active region 110. A first resistive layer 226 is formed over the third mirror region 224, and a second resistive layer 228 is formed over the first resistive layer 226. Each of the layers may be epitaxially grown.

FIG. 4(a) shows a step in the formation of the resistive structure. This step involves forming a mask 232 over the second resistive layer 228. The mask 232 defines the boundaries of the resistive portion and subsequently the inner and outer regions 120, 122 of the VCSEL.

FIG. 4(b) shows a subsequent step of performing an etching process to remove the area of the second resistive layer 228 that is not covered by the mask 232.

FIG. 4(c) shows a subsequent step of performing an etching process to remove the first resistive layer 226 that is not covered by the mask 232.

FIG. 4(d) shows a final step in the formation of the resistive structure, this step involves removing the mask and cleaning the device. After this step, a mirror region of the upper DBR is epitaxially grown over the resistive structure. The upper DBR is epitaxially grown over the entire surface of the device, for example it is grown over the resistive portion 116 in the outer region 122 and the etched portion and the mirror region 224 in the inner region 120.

Epitaxially regrown structures allow for small lithographically defined lateral sizes, low threshold current, and improved thermal management.

The material used for the first resistive layer 226 and the second resistive layer 228 could be InGaP and GaAs respectively, but are not limited to this combination. The two materials used for the first resistive layer 226 and the second resistive layer 228 have a high etch selectivity. In other words, the two materials used for the first resistive layer 226 and the second resistive layer 228 etch at significantly different etch rates when exposed to a given etchant. The materials used for the mirror region 224 and the second resistive layer 228 have similar etch properties.

The regrowth interface can terminate at the same material in both the etched and masked regions, this is advantageous as then regrowth can be performed using the same overpressure gas for the both the inner and outer regions 120, 122. When using this method, the surface of the layers 224, 228 at the regrowth interface is coated or contaminated with residues of mask material such as photoresist or PMMA or hard mask. Additional cleaning, such as O2 plasma ash, diluted HF wash, may be performed after the mask 232 is removed and before the subsequent regrowth process.

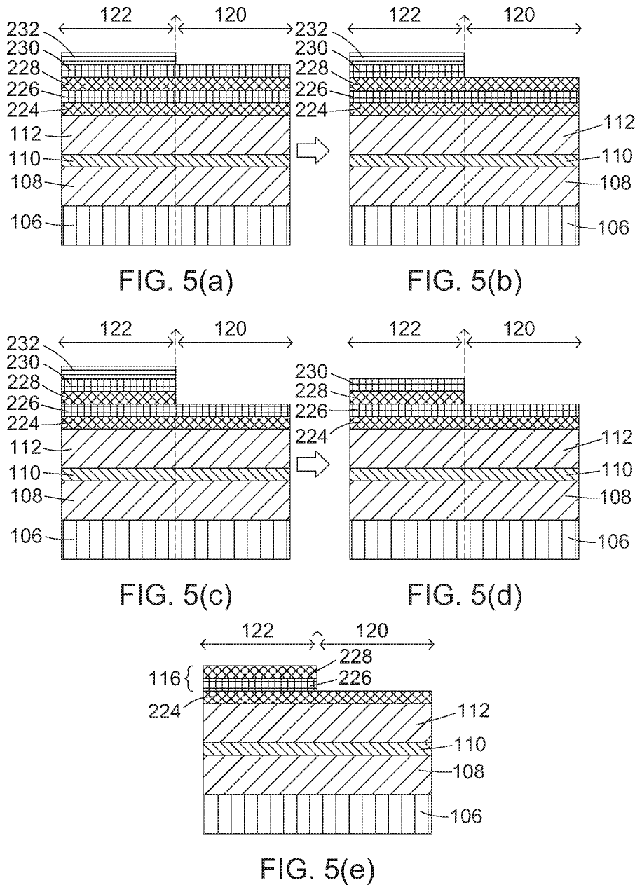

FIG. 5 (referring collectively to FIGS. 5(a) to 5(e)) shows an alternative method for manufacturing a resistive structure in a VCSEL, such as that shown in FIGS. 1 and 3. This method includes forming a third mirror region 224 over a lower DBR 106 and a laser cavity 108, 112 including an active region 110. A first resistive layer 226 is formed over the third mirror region 224, and a second resistive layer 228 is formed over the first resistive layer 226. In this method, a further semiconductor layer 230 is formed over the second resistive layer 228. Each of the layers may be epitaxially grown.

FIG. 5(a) shows a step in the formation of the resistive structure. This step involves forming a mask 232 over the semiconductor layer 230 by photo lithography or electron beam lithography. The mask layer can be a photoresist or PMMA. The mask 232 defines the boundaries of the resistive portion and subsequently the inner and outer regions 120, 122 of the VCSEL.

FIG. 5(b) shows a subsequent step of performing an etching process to remove the semiconductor layer 230 that is not covered by the mask 232. Then, the semiconductor layer 230 is selectively etched, automatically stopping on the material of the second resistive layer 228. This step is performed after the step shown in FIG. 5(a).

FIG. 5(c) shows a subsequent step of performing an etching process to remove the area of the second resistive layer 228 that is not covered by the mask 232. The second resistive layer 228 is selectively etched stopping on the material of the first resistive layer 226 beneath it. The etching process of this step uses a different etchant to the etching process of the step shown in FIG. 5(b). This step is performed after the step shown in FIG. 5(b).

FIG. 5(d) shows a subsequent step in the formation of the resistive structure, this step involves removing or stripping off the mask 232 and cleaning the device.

FIG. 5(e) shows a final step in the formation of the resistive structure, this step involves performing a full wafer etch to the device to remove the exposed semiconductor layer 230 and the first resistive layer 226. After this step, a mirror region of the upper DBR is epitaxially grown over the resistive structure. The mirror region of the upper DBR is epitaxially grown over the entire surface of the device; for example, the mirror region is grown over the resistive portion 116 in the outer region 122 and the etched portion and the mirror region 224 in the inner region 120.

The semiconductor layer 230 may be formed of the same material as the first resistive layer 226 or may be formed of a different material having similar etch properties as the first resistive layer 226 such that both layers are etched in the step shown in FIG. 5(e). The mirror region 224 may be formed of the same material as the second

resistive layer 228 or may be formed of a different material having similar etch properties as the second resistive layer 228, such that the etching step shown in FIG. 5(e) terminates at both these layers. The layer stack may be formed of alternating layers of two materials such that the stack has an ‘ABAB’ structure. There is a low etch selectivity between the materials used for the mirror region 224 and the second resistive layer 228 and the materials used for the semiconductor layer 230 and the first resistive layer 226.

The materials used for the mirror region 224, the first and second resistive layers 226, 228, and the semiconductor layer 230 can be alternating layers of GaAs and InGaP or vice versa, but are not limited to these materials. For example, any other two materials that have good etching selectivity can be used. The two etchants may be hydrogen peroxide and phosphoric acid in deionized water (H2O2:HsPO4:DI H2O) and hydrochloric acid in deionized water (HCI: DI H2O), and can be used to etch the GaAs and InGaP layers respectively.

As an etching step is performed after the removal of the mask, the regrowth interface will be an etched and clean surface. This regrowth interface was never directly coated with photoresist or any other mask material during patterning and etching, so that it is free of foreign material contamination. There is no requirement for a further plasma clean to be performed on the regrowth interface. The clean regrowth interface improves the efficiency of the laser performance, as well as avoids introducing contamination into the regrowth chamber.

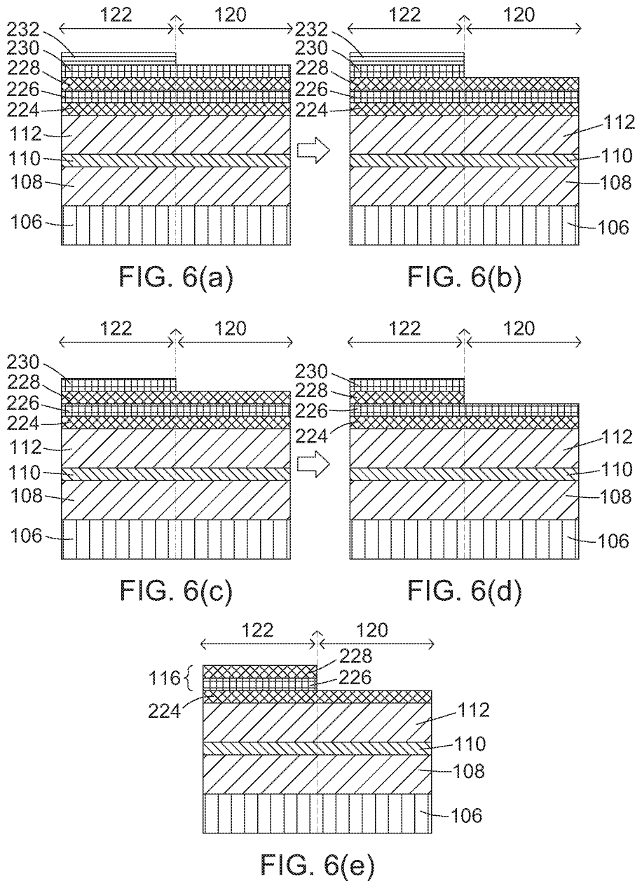

FIG. 6, (referring collectively to FIGS. 6(a)-6 (e)) shows a further, alternative method for manufacturing a resistive structure in a VCSEL. This method is similar to that shown in FIG. 5, however the mask removal step of FIG. 5(d) and shown in FIG. 6(c) is performed before the second etching step of FIG. 5(c) and shown in FIG. 6(c).

Accordingly, the process for manufacturing the light source or VCSEL 100 of FIG. 1 includes application, typically by heteroepitaxial growth, of one or more undoped semiconductor materials or semiconductor materials of a different type which form the (not yet structured) blocking layer;

structuring the deposited one or more layers to form a window or etched portion, as shown in FIGS. 4 to 6;

thereafter: depositing, typically by heteroepitaxial growth, one or more further layers onto the structured blocking layer or resistive structure, e.g., the DBR layers.

Although specific embodiments have been described above, the claims are not limited to those embodiments. Each feature disclosed may be incorporated in any of the described embodiments, alone or in an appropriate combination with other features disclosed herein.

### REFERENCE NUMERALS

100 Light source 120 Inner region
102 Contact 122 Outer region
104 Substrate 134 Second mirror region
106 Lower distributed Bragg reflector 136 Third mirror region
108 Lower cavity spacer 200 VCSEL array
110 Active region 224 Third mirror region
112 Upper cavity spacer 226 First resistive layer
114 Upper distributed Bragg reflector 228 Second resistive layer
116 Resistive portion 230 Semiconductor layer
118 Contact 232 Mask

What is claimed is:

1. A semiconductor vertical cavity surface emitting laser (VCSEL), comprising:
a first mirror region forming a lower distributed Bragg reflector;
a lower cavity spacer layer located over the lower distributed Bragg reflector;
an active region located over the lower cavity spacer layer;
an upper cavity spacer layer located over the active region;
a second mirror region located over the upper cavity spacer layer,
wherein the second mirror region forms an upper distributed Bragg reflector, and
wherein the upper distributed Bragg reflector and the lower distributed Bragg reflector define a vertical resonant cavity, and wherein the vertical resonant cavity comprises an inner region and an outer region, and
a resistive structure located between the upper cavity spacer layer and the second mirror region, wherein the resistive structure comprises:
a resistive portion in the outer region and an etched portion located in the inner region of the vertical resonant cavity, such that a conducting channel is formed in the inner region.

2. The semiconductor VCSEL according to claim 1, wherein the resistive structure is configured such that a first resonant wavelength of the inner region of the vertical resonant cavity is different to a second resonant wavelength of the outer region of the vertical resonant cavity.

3. The semiconductor VCSEL according to claim 1, further comprising a third mirror region located between the upper cavity spacer layer and the resistive structure, wherein the second mirror region and the third mirror region form the upper distributed Bragg reflector.

4. The semiconductor VCSEL according to claim 3, wherein the second mirror region is in direct contact with the third mirror region in the inner region.

5. The semiconductor VCSEL according to claim 3, wherein the resistive structure comprises a first resistive layer, wherein the third mirror region and the first resistive layer have a high etch selectivity.

6. The semiconductor VCSEL according to claim 5, wherein the resistive structure further comprises a second resistive layer, wherein the second resistive layer is located over the first resistive layer and wherein the first resistive layer and the second resistive layer have a high etch selectivity.

7. A semiconductor VCSEL according to claim 1, wherein the resistive portion is configured such that the outer region of the vertical resonant cavity has a lower effective refractive index than the effective refractive index of the inner region.

8. A semiconductor VCSEL according to claim 1, wherein the resistive portion has an optical thickness which is greater than a quarter wavelength of the first resonant wavelength of the inner region and less than a half wavelength of the first resonant wavelength of the inner region.

9. A semiconductor VCSEL according to claim 1, wherein the resistive portion is configured such that the outer region of the vertical resonant cavity has a higher effective refractive index than the effective refractive index of the inner region of the vertical resonant cavity.

10. The semiconductor VCSEL according to claim 1, wherein the resistive portion has an optical thickness which is less than a quarter wavelength of the first resonant wavelength of the inner region or greater than a half wavelength of the first resonant wavelength of the inner region.

11. The semiconductor VCSEL according to claim 1, wherein the resistive portion comprises at least one epitaxially grown layer.

12. The semiconductor VCSEL according to claim 1, wherein the second mirror region is epitaxially grown over the resistive portion and the etched portion.

13. The semiconductor VCSEL according to claim 1, wherein the resistive portion comprises an undoped semiconductor.

14. The semiconductor VCSEL according to claim 1, wherein the upper distributed Bragg reflector comprises a semiconductor material of a first conductivity type and wherein the resistive portion comprises a semiconductor material of a second conductivity type.

15. A VCSEL array comprising a plurality of semiconductor VCSELs according to claim 1, wherein an outer region of a first VCSEL of the plurality of VCSELs is in direct contact with an outer region of a second VCSEL of the at least two semiconductor VCSELs.

16. The VCSEL array according to claim 15, wherein the plurality of VCSELs are configured such that leaked radiation from the inner region of a first VCSEL of the plurality of VCSELs interferes with leaked radiation from the inner region of a second VCSEL of the plurality of VCSELs.

17. A method for manufacturing a semiconductor VCSEL, comprising:
forming a first mirror region forming a lower distributed Bragg reflector;
forming a lower cavity spacer layer located over the lower distributed Bragg reflector;
forming an active region located over the lower cavity spacer layer; forming an upper cavity spacer layer located over the active region;
forming a second mirror region located over the upper cavity spacer layer, wherein the second mirror region forms an upper distributed Bragg reflector, and
wherein the upper distributed Bragg reflector and the lower distributed Bragg reflector define a vertical resonant cavity, and wherein the vertical resonant cavity comprises an inner region and an outer region, and
forming a resistive structure located between the upper cavity spacer layer and the second mirror region, wherein the resistive structure comprises:
a resistive portion in the outer region and an etched portion located in the inner region of the vertical resonant cavity, such that a conducting channel is formed in the inner region, and
wherein forming the resistive structure comprises:
forming a first resistive layer;
forming a second resistive layer over the first resistive layer, wherein the first resistive layer and the second resistive layer have a high etch selectivity;
forming a semiconductor layer over the second resistive layer, wherein the semiconductor layer and the second resistive layer have a high etch selectivity, and wherein the semiconductor layer and the first resistive layer have a low etch selectivity;
forming a mask over the semiconductor layer and patterning the mask to define the inner region;
selectively etching the semiconductor layer in the inner region;
selectively etching the second resistive layer in the inner region;
removing the mask; and
after removing the mask, etching the semiconductor layer in the outer region and the first resistive layer in the inner region.
